(19) United States
(12) Patent Application Publication
(10) Pub. No.: US 2009/0252892 A1
(43) Pub. Date: Oct. 8, 2009

(54) PROCESSING CHAMBER

(75) Inventor: Jurgen Weichart, Balzers (LI)

Correspondence Address: PEARNE & GORDON LLP, 1801 EAST 9TH STREET, SUITE 1200, CLEVELAND, OH, 44114-3108, US

(73) Assignee: OC OERLIKON BALZERS AG, Balzers (LI)

(21) Appl. No.: 12/409,594

(22) Filed: Mar. 24, 2009

Related U.S. Application Data
(60) Provisional application No. 61/039,185, filed on Mar. 25, 2008.

(51) Int. Cl. C23C 16/50; C23C 16/00; H01L 21/677

(52) U.S. Cl. 427/569; 118/723 R; 414/806

(57) ABSTRACT

A process apparatus for treatment of a substrate comprising a load chamber for loading the substrate, a process chamber for processing the substrate, a sealing plane separating the process chamber from the load chamber and means for vertically moving the substrate from the load chamber to the process chamber, and a method for treating the substrate are provided. The load chamber is located in one of the lower and upper portions of the process apparatus, and the process chamber is located in the other of the lower and upper portions of the process apparatus. The process apparatus and method of the present invention will provide easy maintenance and reduced costs by reducing the number of movements for loading the substrate.

### BACKGROUND OF THE INVENTION

The present invention relates generally to a process chamber for treatment of a substrate such as a semiconductor wafer, and a method of treating the substrate. In particular, the invention relates to a process chamber for treatment of a substrate which will provide easy maintenance and reduced costs by reducing the number of movements for loading the substrate, and a method of treating the substrate.

A prior art semiconductor wafer processing system (“cluster tool”) has a central handler, a transport chamber, and several process chambers. The central handler is located inside the transport chamber, and the process chambers are attached to the transport chamber. The process chambers are separated from the central handler by isolation gate valves.

During normal operation, the handler holds a substrate and laterally moves the substrate above one of the process chambers. Then, the handler vertically moves the substrate down into the designated process chamber by placing the substrate on a set of pins. Thus, at least two movements which are the lateral movement and the vertical movement are required for moving the substrate into the process chamber. In order to lower the cost for loading the substrate, it is necessary to reduce the number of the movements to one. The reduction of the number of the movements will also help reduce the generation of particles during the operation.

The present invention will solve the above-described problems by developing a novel process chamber for treatment of a substrate and a method of treating the substrate which will easy maintenance and reduced costs by reducing the number of movements for loading the substrate.

### SUMMARY OF THE INVENTION

The present invention, in one aspect, concerns, a process apparatus for treatment of a substrate comprising a load chamber for loading the substrate, a process chamber for processing the substrate, a sealing plane separating the process chamber from the load chamber, and means for vertically moving the substrate. The load chamber is located in one of the lower and upper portions of the process apparatus, and the process chamber is located in the other of the lower and upper portions of the process apparatus. The means for vertically moving the substrate moves the substrate from the load chamber to the process chamber.

In a further aspect, the load chamber is located in the lower portion of the process apparatus, and the process chamber is located in the upper portion of the process apparatus.

In a further aspect, the load chamber is located in the upper portion of the process apparatus, and the process chamber is located in the lower portion of the process apparatus.

In a further aspect, the process apparatus comprises first and second openings for loading and unloading the substrate. The first opening is opposed to the second opening.

In a further aspect, the process apparatus is cylindrical and has symmetric interfaces.

In a further aspect, the process chamber performs PVD processing to the substrate.

According to a further aspect, the present invention also provides a method for treating a substrate in a process apparatus having a load chamber for loading the substrate, a process chamber for processing the substrate, a sealing plane separating the process chamber from the load chamber, and means for vertically moving the substrate. The load chamber is located in one of the lower and upper portions of the process apparatus, and the process chamber is located in the other of the lower and upper portions of the process apparatus. The method comprises the steps of loading the substrate to the load chamber; moving vertically the substrate from the load chamber to the process chamber by the vertically moving means through the sealing plane; treating the substrate in the process chamber; and unloading the substrate from the process chamber.

In a further aspect, the load chamber is located in the lower portion of the process apparatus, and the process chamber is located in the upper portion of the process apparatus.

In a further aspect, the load chamber is located in the upper portion of the process apparatus, and the process chamber is located in the lower portion of the process apparatus.

In a further aspect, the process apparatus has first and second openings for loading and unloading the substrate. The first opening is opposed to the second opening.

In a further aspect, the process apparatus is cylindrical and has symmetric interfaces.

In a further aspect, the treating step comprises performing PVD processing to the substrate.

### BRIEF DESCRIPTION OF THE DRAWINGS

The foregoing and other aspects of the present invention will become apparent to those skilled in the art to which the present invention relates upon reading the following description with reference to the accompanying drawings, in which:

FIG. 1 is a top view of a process apparatus according to the present invention.

FIG. 2 is a cross sectional view of one embodiment of a process apparatus according to the present invention.

FIG. 3 is a cross sectional view of another embodiment of a process apparatus according to the present invention.

### DETAILED DESCRIPTION OF AN EMBODIMENT OF THE INVENTION

Examples of embodiments that incorporate one or more aspects of the present invention are described and illustrated in the drawings. These illustrated examples are not intended to be a limitation on the present invention. For example, one or more aspects of the present invention can be utilized in other embodiments and even other types of devices. Moreover, certain terminology is used herein for convenience only and is not to be taken as a limitation on the present invention. Still further, in the drawings, the same reference numerals are employed for designating the same elements.

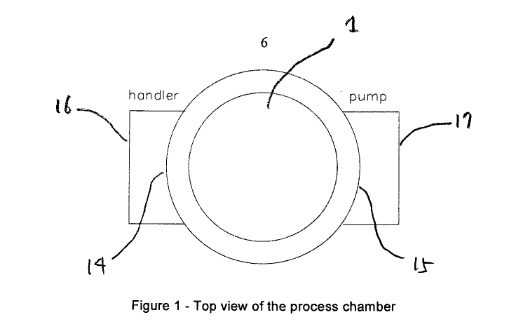

Referring to FIG. 1, there is illustrated a process apparatus 1 for treatment of a substrate according to the present invention. The process apparatus 1 shown in FIG. 1 is cylindrical. The process apparatus 1 has two opposed openings 14, 15. A handler 16 is attached to one opening 14, and a pump 17 is attached to another opening 15.

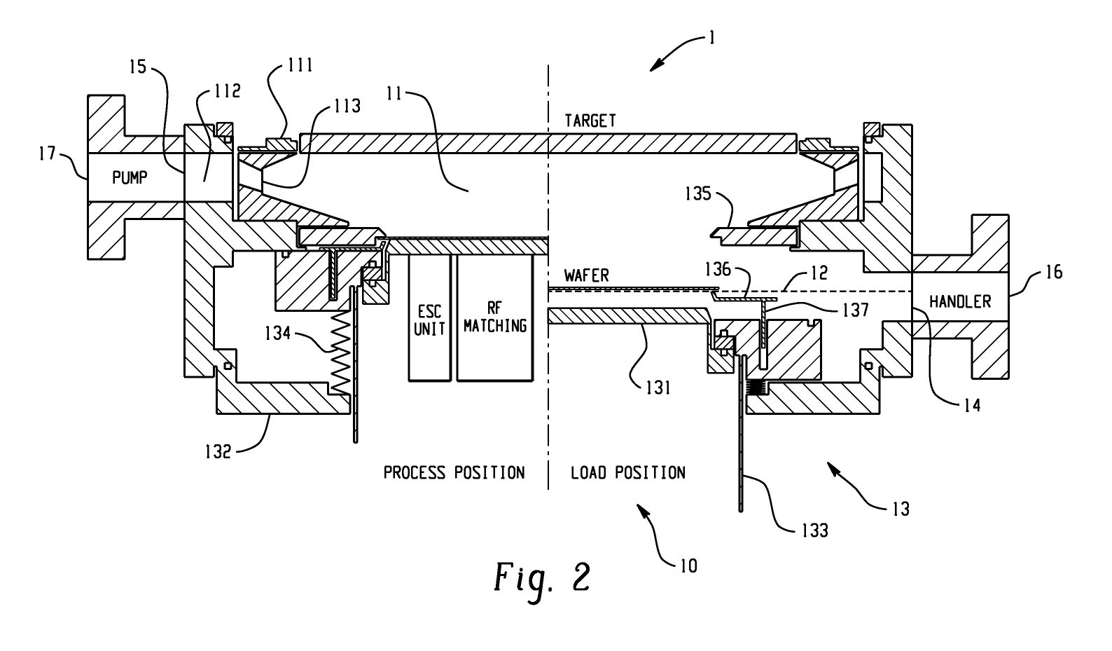

FIG. 2 shows a first embodiment of the process apparatus for treatment of a substrate according to the present invention. As is shown in FIG. 2, the process apparatus 1 has a load chamber 10, a process chamber 11, a sealing plane 12 separating the process chamber 11 from the load chamber 10, and means 13 for vertically moving the substrate from load chamber 10 to the process chamber 11. The process apparatus 1 is preferably cylindrical and has symmetric interfaces. The process apparatus 1 may be cut from one single piece of aluminum. The load chamber 10 is located in the lower portion of the process apparatus 1. On the other hand, the process chamber 11 is located in the upper portion of the process apparatus 1. As is shown in FIG. 2, the process chamber 11 is closed in the process position by the sealing plane 12.

The process apparatus 1 has two side openings 14, 15. One side opening 14 is opposed to another side opening 15. A handler 16 is located on the lower right side of the process apparatus 1, and attached to the side opening 14. A pump 17 is located on the upper left side of the process apparatus 1, and attached to the side opening 15. The pump 17 may be attached to the process chamber 11 via a gate valve (not shown). The gate valve is especially needed, if the pump 17 is a cryo pump.

The vertically moving means 13 has a chuck 131, a chuck flange 132, a chuck drive system 133, a vacuum sealing bellow 134, a clamp ring 135, a lift ring 136, and at least three lift ring pins 137. The chuck flange 132 carries the chuck 131 from a load position to a process position. The drive system 133 drives the chuck 131. The lift ring 136 may be spring loaded to allow retraction or driven by other means. The lift ring 136, the pins 137 and the chuck 131 may be insulated from the support body, since electric power may be applied to the chuck 131.

The process chamber 11 has a source flange 111, a gas ring 112 and an anode shield 113. A sputter source (not shown) is attached to the source flange 111 which is insulated by a source insulator. The sputter source supplies gas to the process chamber 11 through the gas ring 112. The anode shield 113 provides a counter-electrode to the substrate (such as a wafer, etc.) and protects the inner surfaces of the process chamber 111 from being coated. For maintenance reasons, the anode shield 113 is preferably a single piece shield. The clamp ring 135 is not in contact with the anode shield 113 in order to avoid pressure on the edge of the wafer. In order to do so, the weight of the clamp ring 135 is balanced with the weight of the spring of the lift ring 136.

The following illustrate the operations of treating a wafer in the process apparatus 1 of the present invention.

A wafer is loaded to the lift ring 136 via the handler port of the handler 16 with the chuck 131 being in a load position. The clamp ring 135 is sitting on a machined edge of the process apparatus 1. The lift ring 136 is lifted by the at least three pins 137 so that the wafer can be moved in between the lift ring 136 and the clamp ring 137 and lay down on the lift ring 136 by the vertical move of the handling system. Then, after the handling arm is retracted, the chuck 131 is moved up from the load position to the process position. The lift ring pins 137 are moved into their sheath. Then, the clamp ring 135 is moved up from its rest position and holds the wafer in place inside the process chamber 11.

Now, a process gas (e.g., Argon) is introduced from the sputter source via the gas ring 112 to the process chamber 11. The gas ring 112 is protected from being coated by the anode shield 113. The process gas is applied on the wafer. After a sufficient amount of the process gas is applied on the wafer, the supply of the process gas is stopped.

For maintenance, the process chamber 11 is vented in the process position. The load chamber 10 is not vented since the sealing plane 12 prevents the load chamber 10 from being vented. The load chamber 10 is now pumped via the handler 16. The target (wafer) is lifted or swiveled away to allow access to all parts to be maintained. The target, the anode shield 113, and the clamp ring 135 are usually exchanged. The broken pieces of the wafer may also be removed from the process chamber 11.

Then, the wafer is unloaded from process chamber 11 to the load chamber 10, and discharged via the handler 16.

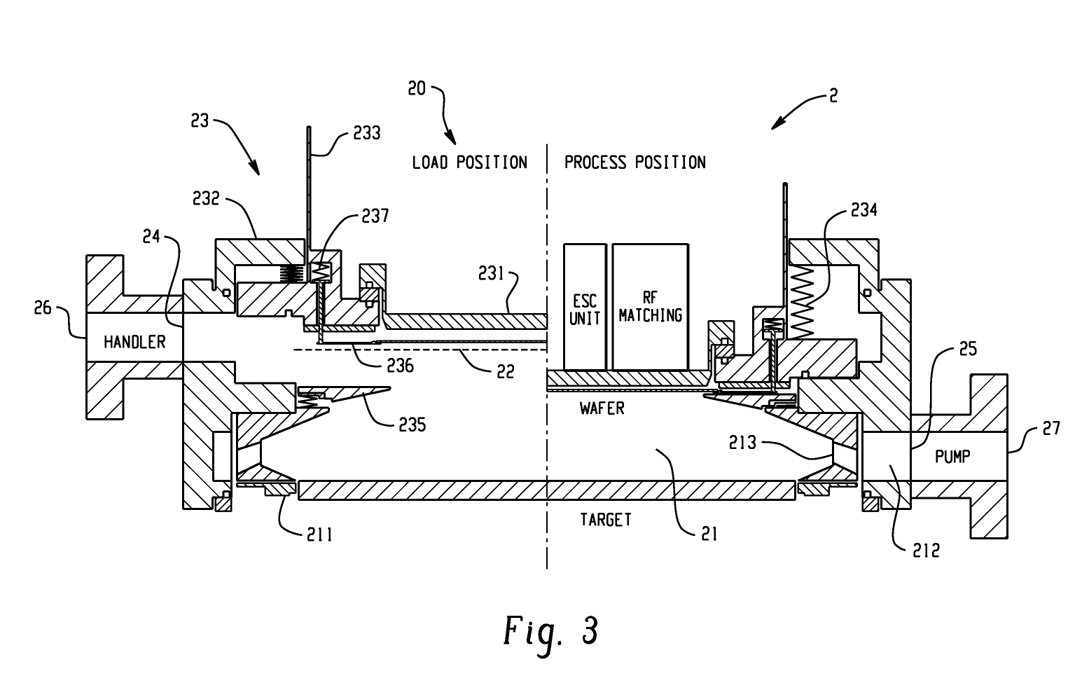

FIG. 3 shows a second embodiment of the process apparatus for treatment of a substrate according to the present invention. As is shown in FIG. 3, the process apparatus 2 has a load chamber 20, a process chamber 21, a sealing plane 22 separating the process chamber 21 from the load chamber 20, and means 23 for vertically moving the substrate from load chamber 20 to the process chamber 21. The process apparatus 2 is also preferably cylindrical and has symmetric interfaces, and may be cut from one single piece of aluminum. Unlike the first embodiment of the process apparatus, the load chamber 20 is located in the upper portion of the process apparatus 2 and the process chamber 21 is located in the lower portion of the process apparatus 2. The other parts are the same as the first embodiment, except the handler and the pump are exchanged, the top load chamber 20 is connected to the handler and the chuck flange, and the sputter source is attached to the bottom process chamber 21. As is shown in FIG. 3, the process chamber 21 is closed in the process position by the sealing plane 22.

The process apparatus 2 has two side openings 24, 25. One side opening 24 is opposed to another side opening 25. A handler 26 is located on the upper right side of the process apparatus 2, and attached to the side opening 24. A pump 27 is located on the lower left side of the process apparatus 2, and attached to the side opening 25.

The vertically moving means 23 has a chuck 231, a chuck flange 232, a chuck drive system 233, a vacuum sealing bellow 234, a clamp ring 235, a wafer support ring 236, and at least three spring loaded pins 237. The wafer support ring 236 is spring loaded in order not to break the wafer by the applied pressure. The wafer support ring 236 is also insulated to enable the application of electric power to the chuck 231.

The process chamber 21 has a source flange 211, a gas ring 212 and an anode shield 213. A sputter source (not shown) is attached to the source flange 211 which is insulated by a source insulator. The sputter source supplies gas to the process chamber 21.

The following illustrate the operations of treating a wafer in the process apparatus 1 of the present invention.

A wafer is loaded to the wafer support ring 236 via the handler port of the handler 26 with the chuck 231 being in a load position, and placed on the wafer support ring 236 by the vertical move of the handling system. The wafer support ring 236 is held down by the at least three spring loaded pins 237. Then, after the handling arm is retracted, the chuck 231 is moved down from the load position to the process position. By moving the chuck 231 down, the wafer and the wafer support ring 236 are in contact with the clamp ring 235. The spring loaded pins 237 are moved in their sheaths which are also insulated from the grounded support body.

Now, a process gas (e.g., Argon) is introduced from the sputter source to the process chamber 21. The gas ring 212 is protected from being coated by the anode shield 213. The process gas is applied on the wafer. After a sufficient amount of the process gas is applied on the wafer, the supply of the process gas is stopped.

For maintenance, the process chamber 21 is vented in the process position. The sealing plane 22 prevents the load chamber 20 from being vented. The load chamber 20 is now pumped via the handler 26. The target (wafer), the anode shield 213 and the speing loaded clamp ring 235 can be removed from the bottom.

In this embodiment, the sputter source is attached to the bottom of the process chamber 21. This bottom-up sputter option has advantages for backside metallization, since water flipping is not needed anymore. It is also expected to reduce the particle counts.

Alternatively, instead of placing the sputter source, an etch station, a degas station, a cooling station or a metrology station may be attached to either side of these basic process modules. Stations which have been originally designed for the front application, such as radiation heaters, may be attached to the back side and vice versa.

The invention has been described with respect to various specific embodiments. However, it will be recognized by those skilled in the art that the invention can be practiced with modifications that are within the spirit and scope of the claims that follow.

What is claimed is:

1. A process apparatus for treatment of a substrate comprising:
a load chamber for loading said substrate;
a process chamber for processing said substrate;
a sealing plane separating said process chamber from said load chamber; and
means for vertically moving said substrate from said load chamber to said process chamber,
wherein said load chamber is located in one of the lower and upper portions of said process apparatus, and said process chamber is located in the other of the lower and upper portions of said process apparatus.

2. The apparatus of claim 1, wherein said load chamber is located in the lower portion of said process apparatus, and said process chamber is located in the upper portion of said process apparatus.

3. The apparatus of claim 1, wherein said load chamber is located in the upper portion of said process apparatus, and said process chamber is located in the lower portion of said process apparatus.

4. The apparatus of claim 1, further comprising first and second openings for loading and unloading said substrate, wherein said first opening is opposed to said second opening.

5. The apparatus of claim 1, wherein said process apparatus is cylindrical and has symmetric interfaces.

6. The apparatus of claim 1, wherein said process chamber performs PVD processing to said substrate.

7. A method for treating a substrate in a process apparatus having a load chamber for loading said substrate, a process chamber for processing said substrate, a sealing plane separating said process chamber from said load chamber, and means for vertically moving said substrate from said load chamber to said process chamber, wherein said load chamber is located in one of the lower and upper portions of said process apparatus, and said process chamber is located in the other of the lower and upper portions of said process apparatus, said method comprising the steps of:
loading said substrate to said load chamber;
moving vertically said substrate from said load chamber to said process chamber by the vertically moving means through said sealing plane;
treating said substrate in said process chamber; and
unloading said substrate from said process chamber.

8. The method of claim 7, wherein said load chamber is located in the lower portion of said process apparatus, and said process chamber is located in the upper portion of said process apparatus.

9. The method of claim 7, wherein said load chamber is located in the upper portion of said process apparatus, and said process chamber is located in the lower portion of said process apparatus.

10. The method of claim 7, wherein said process apparatus has first and second openings for loading and unloading said substrate, and wherein said first opening is opposed to said second opening.

11. The method of claim 7, wherein said process apparatus is cylindrical and has symmetric interfaces.

12. The method of claim 7, wherein said treating step comprises performing PVD processing to said substrate.
